(19) United States
(12) Patent Application Publication
(10) Pub. No.: US 2025/0309213 A1
(43) Pub. Date: Oct. 2, 2025

(54) METHOD OF MANUFACTURING SEMICONDUCTOR STRUCTURE INCLUDING HORIZONTALLY ARRANGED MEMORY DIES

(71) Applicant: NANYA TECHNOLOGY CORPORATION, NEW TAIPEI CITY (TW)

(72) Inventor: SHING-YIH SHIH, NEW TAIPEI CITY (TW)

(21) Appl. No.: 18/664,606

(22) Filed: May 15, 2024

Related U.S. Application Data
(62) Division of application No. 18/624,371, filed on Apr. 2, 2024.

(51) Int. Cl. H01L 25/18; H01L 23/00; H01L 23/48; H01L 23/498

(52) U.S. Cl. CPC H01L 25/18; H01L 23/481; H01L 23/49833; H01L 24/32; H01L 2224/32225; H01L 2924/1815

(57) ABSTRACT

A semiconductor structure includes: a logic wafer; a first front-side redistribution layer (RDL), disposed over the logic wafer; a first memory die, disposed over the first front-side RDL; a second memory die, disposed over the first front-side RDL, wherein the first memory die and the second memory die are horizontally arranged; and a first interconnect die, disposed over the first front-side RDL between the first memory die and the second memory die, wherein the first memory die is electrically connected to a first via in the first interconnect die, and the second memory die is electrically connected to a second via in the first interconnect die. A method of manufacturing the semiconductor structure is also provided.

### CROSS-REFERENCE TO RELATED APPLICATION

This application is a divisional application of U.S. Non-Provisional application Ser. No. 18/624,371 filed Apr. 2, 2024, which is incorporated herein by reference in its entirety.

### TECHNICAL FIELD

The present disclosure relates to a semiconductor structure and a method of manufacturing the semiconductor structure. Particularly, the present disclosure relates to a semiconductor structure including horizontally arranged memory dies and a method of manufacturing the semiconductor structure.

### DISCUSSION OF THE BACKGROUND

Semiconductor devices are used in a variety of electronic applications, such as personal computers, cellular phones, digital cameras, and other electronic equipment. The semiconductor devices are typically fabricated by sequentially depositing insulating or dielectric layers, conductive layers, and semiconductive layers of material over a semiconductor substrate, and patterning the various material layers using lithography to form circuit components and elements thereon. As the semiconductor industry has progressed into advanced technology process nodes in pursuit of greater device density, higher performance, and lower costs, challenges of improved performance without increased size have arisen.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure includes: a logic wafer; a first front-side redistribution layer (RDL), disposed over the logic wafer; a first memory die, disposed over the first front-side RDL; a second memory die, disposed over the first front-side RDL, wherein the first memory die and the second memory die are horizontally arranged; and a first interconnect die, disposed over the first front-side RDL between the first memory die and the second memory die, wherein the first memory die is electrically connected to a first via in the first interconnect die, and the second memory die is electrically connected to a second via in the first interconnect die.

Another aspect of the present disclosure provides a semiconductor structure. The semiconductor structure includes: a first reconstructed chip, disposed over a logic wafer; and a second reconstructed chip, disposed vertically over the first reconstructed chip. The first reconstructed chip includes: a first front-side redistribution layer (RDL); a first memory die, disposed over the first front-side RDL; a second memory die, disposed over the first front-side RDL, wherein the second memory die and the first memory die are horizontally arranged; and a first interconnect die, disposed over the first front-side RDL and between the first memory die and the second memory die. The second reconstructed chip includes: a second front-side RDL; a third memory die, disposed over the second front-side RDL, wherein a thickness of the third memory die is substantially greater than a thickness of the first memory die; and a fourth memory die, disposed over the second front-side RDL and adjacent to the third memory die, wherein a thickness of the fourth memory die is substantially greater than a thickness of the second memory die.

Another aspect of the present disclosure provides a method for manufacturing a semiconductor structure. The method includes a number of operations. A first reconstructed chip is formed. A second reconstructed chip is formed. The first reconstructed chip is disposed over a logic wafer. The second reconstructed chip is disposed over the first reconstructed chip. The formation of the first reconstructed chip includes a number of steps. A first memory die, a first interconnect die, and a second memory die are disposed over a first carrier substrate. A first molding material layer is formed over the first carrier substrate and surrounds the first memory die, the first interconnect die, and the second memory die. A first backside redistribution layer (RDL) is formed over the first molding material layer, the first memory die, the first interconnect die, and the second memory die. A first front-side RDL is formed over the first molding material layer, the first memory die, the first interconnect die, and the second memory die opposite to the first backside RDL, thereby forming the first reconstructed chip. The formation of the second reconstructed chip includes a number of steps. A third memory die, a second interconnect die, and a fourth memory die are disposed over a second carrier substrate. A second molding material layer is formed over the second carrier substrate and surrounds the third memory die, the second interconnect die, and the fourth memory die. A second front-side RDL is formed over the second molding material layer, the third memory die, the second interconnect die, and the fourth memory die, thereby forming the second reconstructed chip.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a schematic cross-sectional diagram of a semiconductor structure in accordance with some embodiments of the present disclosure.

FIGS. 2 to 19 are schematic cross-sectional diagrams at different stages of a manufacturing method of a semiconductor structure in accordance with some embodiments of the present disclosure.

FIG. 20 is a schematic cross-sectional diagram of a semiconductor structure in accordance with some embodiments of the present disclosure.

FIG. 21 is a schematic cross-sectional diagram of a semiconductor structure in accordance with some embodiments of the present disclosure.

FIG. 22 is a schematic cross-sectional diagram of a reconstructed chip in accordance with some embodiments of the present disclosure.

FIG. 23 is a schematic cross-sectional diagram of a reconstructed chip in accordance with some embodiments of the present disclosure.

FIG. 24 is a schematic cross-sectional diagram of a semiconductor structure in accordance with some embodiments of the present disclosure.

FIG. 25 is a schematic cross-sectional diagram of a semiconductor package structure in accordance with some embodiments of the present disclosure.

FIG. 26 is a flow diagram illustrating a method of manufacturing a semiconductor structure in accordance with some embodiments of the present disclosure.

FIG. 27 is a flow diagram illustrating steps of an operation of a method of manufacturing a semiconductor structure in accordance with some embodiments of the present disclosure.

FIG. 28 is a flow diagram illustrating steps of an operation of a method of manufacturing a semiconductor structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

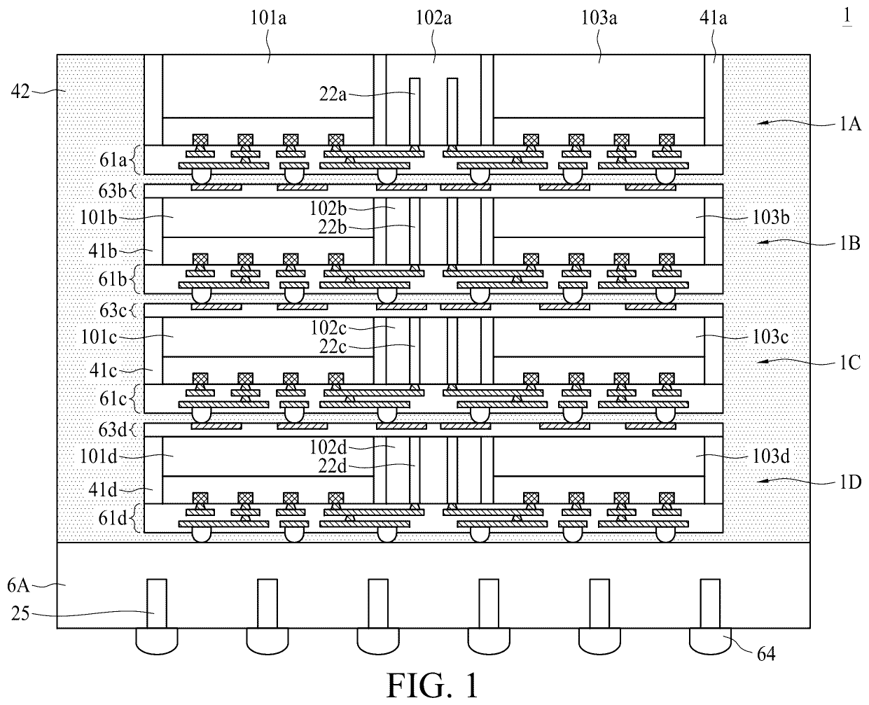

FIG. 1 is a schematic cross-sectional diagram of a semiconductor structure 1 in accordance with some embodiments of the present disclosure. The semiconductor structure 1 is a stacked structure or a packaged structure, and includes a plurality of reconstructed chips 1A, 1B, 1C and 1D vertically stacked over a logic wafer 6A. It should be noted that although the semiconductor structure 1 shown in FIG. 1 includes four reconstructed chips (including the reconstructed chips 1A, 1B, 1C and 1D) over the logic wafer 6A, such arrangement is merely an exemplary embodiment for a purpose of illustration. In other embodiments, more or fewer reconstructed chips can be disposed over the logic wafer 6A, and the number of reconstructed chips is not limited.

The logic wafer 6A can include a plurality of electrical components for processing information to complete a task. In some embodiments, the logic wafer 6A may have a multilayer structure, or the logic wafer 6A may include a multilayer compound semiconductor structure. In some embodiments, the logic wafer 6A includes semiconductor devices, electrical components, electrical elements, or a combination thereof. In some embodiments, the logic wafer 6A includes transistors or functional units of transistors. In some embodiments, the logic wafer 6A includes active components, passive components, and/or conductive elements. The electrical components can include a planar transistor, a multi-gate transistor, a gate-all-around field-effect transistor (GAAFET), a fin field-effect transistor (FinFET), a vertical transistor, a nanosheet transistor, a nanowire transistor, a passive device, a capacitor, or a combination thereof for performing various functions. The active components may include a logic die (e.g., a system-on-a-chip (SoC), a central processing unit (CPU), a graphics processing unit (GPU), an application processor (AP), a microcontroller, etc.), a radio frequency (RF) die, a sensor die, a micro-electro-mechanical-system (MEMS) die, a signal processing die (e.g., a digital signal processing (DSP) die), a front-end die (e.g., an analog front-end (AFE) die) or other active components. The passive components may include a capacitor, a resistor, an inductor, a fuse or other passive components.

The active components and/or passive components as mentioned above can be formed in and/or over a semiconductor substrate. The semiconductor substrate may be a bulk semiconductor, a semiconductor-on-insulator (SOI) substrate, or the like. The semiconductor substrate can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Si:Ge feature in which Si and Ge compositions change from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy.

The logic wafer 6A further includes an interconnect structure disposed over the semiconductor substrate and the active components. In some embodiments, the interconnect structure is at a front side of the semiconductor substrate. The interconnect structure may include multiple conductive elements arranged into layers. The conductive elements may include metal lines, metal islands, conductive vias, contacts or other conductive elements. In some embodiments, the interconnect structure includes multiple metal line layers. The interconnect structure may further include multiple metal via layers arranged alternately between the metal line layers for electrical connection between the metal line layers. In some embodiments, each metal line layer is formed of metal lines and an intermetal dielectric (IMD) layer surrounding the metal lines. In some embodiments, each metal via layer is formed of metal vias and an IMD layer surrounding the metal vias.

The logic wafer 6A may further include a plurality of backside via structures 25 extending from a backside of the semiconductor substrate of the logic wafer 6A for electrical connection to the active components or passive components formed on the semiconductor substrate. In some embodiments, the logic wafer 6A further includes a plurality of conductive bumps 64 at the backside of the semiconductor substrate for electrical connection to another wafer, substrate, die or chip. In other embodiments, the conductive bumps 64 can be in a form of pads, balls, or segments. A configuration of the conductive bumps 64 is not limited.

Each of the reconstructed chips 1A, 1B, 1C and 1D may include two horizontally arranged memory dies and an interconnect die disposed horizontally between the two memory dies. In some embodiments, the reconstructed chip 1A is a top reconstructed chip of the stacked reconstructed chips 1A, 1B, 1C and 1D. In some embodiments, the reconstructed chip 1D is a reconstructed chip closest to the logic wafer 6A of the stacked reconstructed chips 1A, 1B, 1C and 1D.

The reconstructed chip 1A may include a first memory die 101a, an interconnect die 102a, a second memory die 103a, a front-side redistribution layer (RDL) 61a, and a molding material layer 41a. In some embodiments, the first memory die 101a, the interconnect die 102a, and the second memory die 103a are horizontally arranged over the front-side RDL 61a. In some embodiments, the interconnect die 102a is disposed between the first memory die 101a and the second memory die 103a. In some embodiments, the molding material layer 41a is disposed over the front-side RDL 61a. In some embodiments, the molding material layer 41a surrounds each of the first memory die 101a, the interconnect die 102a, and the second memory die 103a. In some embodiments, the first memory die 101a and the interconnect die 102a are separated by the molding material layer 41a. In some embodiments, the second memory die 103a and the interconnect die 102a are separated by the molding material layer 41a.

The reconstructed chips 1A, 1B, 1C and 1D may have similar structures. For a purpose of illustration and ease of understanding, a numeral at a front of each element's label represents a function, with similar or same functions in different reconstructed chips 1A, 1B, 1C and 1D. Similarly, an English letter (a, b, c, etc.) after the numeral of each element's label represents which reconstructed chip 1A, 1B, 1C or 1D the element is part of. For example, the reconstructed chip 1B includes a first memory die 101b, an interconnect die 102b, a second memory die 103b, a front-side RDL 61b and a molding material layer 41b; the reconstructed chip 1C includes a first memory die 101c, an interconnect die 102c, a second memory die 103c, a front-side RDL 61c and a molding material layer 41c; and the reconstructed chip 1D includes a first memory die 101d, an interconnect die 102d, a second memory die 103d, a front-side RDL 61d and a molding material layer 41d.

Arrangements of the first memory die 101b, the interconnect die 102b, the second memory die 103b, the front-side RDL 61b and the molding material layer 41b can be similar to the arrangements of the first memory die 101a, the interconnect die 102a, the second memory die 103a, the front-side RDL 61a and the molding material layer 41a as described above. Similarly, arrangements of the first memory die 101c, the interconnect die 102c, the second memory die 103c, the front-side RDL 61c and the molding material layer 41c can be found by referring to the arrangements of the first memory die 101a, the interconnect die 102a, the second memory die 103a, the front-side RDL 61a and the molding material layer 41a; and arrangements of the first memory die 101d, the interconnect die 102d, the second memory die 103d, the front-side RDL 61d and the molding material layer 41d can be found by referring to the arrangements of the first memory die 101a, the interconnect die 102a, the second memory die 103a, the front-side RDL 61a and the molding material layer 41a. Repeated description is omitted herein.

For electrical connection to another reconstructed chip 1A, 1B or 1C, each of the reconstructed chips 1B, 1C and 1D further includes a backside RDL 63b, 63c and 63d, respectively. In some embodiments, the backside RDL 63d is disposed over the first memory die 101d, the interconnect die 102d and the second memory die 103d. In some embodiments, the backside RDL 63d covers the molding material layer 41d. In some embodiments, the backside RDL 63d is bonded to the front-side RDL 61c. In some embodiments, the backside RDL 63c is disposed over the first memory die 101c, the interconnect die 102c and the second memory die 103c. In some embodiments, the backside RDL 63c covers the molding material layer 41c. In some embodiments, the backside RDL 63c is bonded to the front-side RDL 61b. In some embodiments, the backside RDL 63b is disposed over the first memory die 101b, the interconnect die 102b and the second memory die 103b. In some embodiments, the backside RDL 63b covers the molding material layer 41b. In some embodiments, the backside RDL 63b is bonded to the front-side RDL 61a.

The semiconductor structure 1 may further include a molding material layer 42 surrounding the reconstructed chips 1A, 1B, 1C and 1D. In some embodiments, the molding material layer 42 fills a space between the reconstructed chips 1A and 1B. In some embodiments, the molding material layer 42 fills a space between the reconstructed chips 1B and 1C. In some embodiments, the molding material layer 42 fills a space between the reconstructed chips 1C and 1D. In some embodiments, the molding material layer 42 fills a space between the reconstructed chip 1D and the logic wafer 6A. In some embodiments, a top surface of the molding material layer 42 is substantially aligned with a top surface of the reconstructed chip 1A. In some embodiments, the top surface of the molding material layer 42 and the top surface of the reconstructed chip 1A are substantially coplanar.

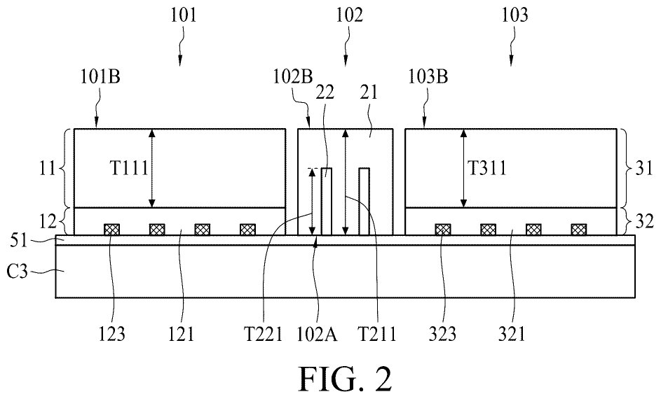

FIGS. 2 to 19 are schematic cross-sectional diagrams at different stages of a manufacturing method of the semiconductor structure 1 in accordance with some embodiments of the present disclosure.

Referring to FIG. 2, a first memory die 101, an interconnect die 102 and a second memory die 103 are disposed over a carrier substrate C1. The carrier substrate C1 is for a purpose of handling and support during the manufacturing process. In some embodiments, the first memory die 101 is separated from and adjacent to the interconnect die 102. In some embodiments, the second memory die 103 is disposed at a side of the interconnect die 102 opposite to the first memory die 101. In some embodiments, the second memory die 103 is separated from and adjacent to the interconnect die 102. In some embodiments, a bonding layer 51 is disposed over the carrier substrate C1. In some embodiments, the first memory die 101 is attached to the carrier substrate C1 through the bonding layer 51. In some embodiments, the interconnect die 102 is attached to the carrier substrate C1 through the bonding layer 51. In some embodiments, the second memory die 103 is attached to the carrier substrate C1 through the bonding layer 51.

The first memory die 101 may include a substrate layer 11 and an interconnect structure 12 disposed at a front side of the substrate layer 11. The substrate layer 11 can be a semiconductor substrate similar to that of the logic wafer 6A as described above. In some embodiments, a plurality of memory units (e.g., a dynamic random-access memory (DRAM), a static random-access memory (SRAM), etc.) are formed on the substrate layer 11. The interconnect structure 12 includes a plurality of conductive elements 123 and an IMD structure 121 surrounding the conductive elements 123. The conductive elements 123 may be grouped into multiple metal line layers and multiple metal via layers alternately arranged with the metal line layers, and the IMD structure 121 may include multiple IMD layers. Details of the interconnect structure 12 are not shown in the figures for a purpose of simplicity. The interconnect structure 12 can be similar to the RDL 61a as described above, and repeated description is omitted herein.

The second memory die 103 can be similar to the first memory die 101. The second memory die 103 may include a substrate layer 31 and an interconnect structure 32 disposed at a front side of the substrate layer 31. The substrate layer 31 can be a semiconductor substrate similar to that of the logic wafer 6A as described above. In some embodiments, a plurality of memory units (e.g., a dynamic random-access memory (DRAM), a static random-access memory (SRAM), etc.) are formed on the substrate layer 31. The interconnect structure 32 includes a plurality of conductive elements 323 and an IMD structure 321 surrounding the conductive elements 323. The conductive elements 323 may be grouped into multiple metal line layers and multiple metal via layers alternately arranged with the metal line layers, and the IMD structure 321 may include multiple IMD layers. Details of the interconnect structure 32 are not shown in the figures for a purpose of simplicity. The interconnect structure 32 can be similar to the RDL 61a as described above, and repeated description is omitted herein.

The interconnect die 102 may include a substrate layer 21 and a plurality of via structures 22 disposed in the substrate layer 21. In some embodiments, the substrate layer 21 includes a bulk semiconductor substrate. In some embodiments, the substrate layer 21 includes silicon or germanium in a single crystal form or a polycrystalline form. Each of the via structures 22 extends from a front surface 102A of the substrate layer 21 toward a back surface 102B of the substrate layer 21. In some embodiments, the via structure 22 is exposed at the front surface 102A. In some embodiments, the via structure 22 stops within the substrate layer 21. In some embodiments, the via structure 22 is separated from the back surface 120B of the substrate layer 21.

It should be noted that the via structures 22 can be formed by a front-end-of-line (FEOL) semiconductor manufacturing process (also known as a FEOL process). Therefore, a dimension and quality of the via structures 22 can be effectively controlled compared to other types of via structures, e.g., a through-molding via structure or a through-dielectric via structure, which are formed by back-end-of-line (BEOL) semiconductor manufacturing processes (also known as BEOL processes). In some embodiments, a depth T221 of the via structure 22 measured from the front surface 102A of the substrate layer 21 is in a range of 30 to 70 microns (μm).

In some embodiments, at this stage, a thickness T111 of the substrate layer 11 of the first memory die 101 is substantially equal to a thickness T311 of the substrate layer 31 of the second memory die 103. In some embodiments, the thickness T111 or the thickness T311 is in a range of 500 to 750 μm. In some embodiments, a thickness T211 of the substrate layer 21 of the interconnect die 102 is substantially greater than or equal to the thickness T111 or the thickness T311. In some embodiments, the thickness T211 is in a range of 500 to 750 μm.

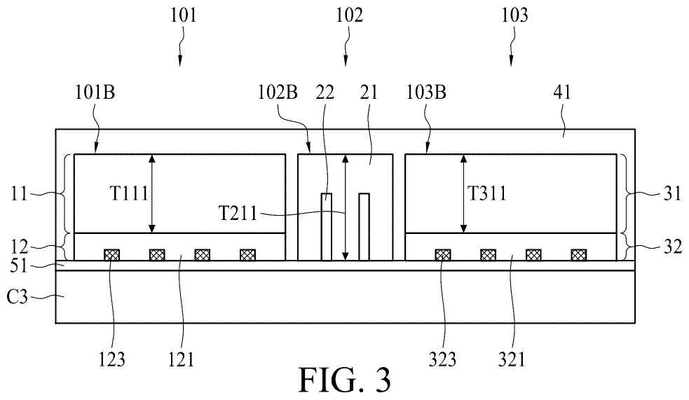

Referring to FIG. 3, a molding material layer 41 is formed over the carrier substrate C1. The molding material layer 41 covers the first memory die 101, the interconnect die 102 and the second memory die 103. In some embodiments, the molding material layer 41 fills a space between the first memory die 101 and the interconnect die 102. In some embodiments, the molding material layer 41 fills a space between the second memory die 103 and the interconnect die 102. In some embodiments, the molding material layer 41 covers a front surface of the carrier substrate C1, wherein the front surface of the carrier substrate Cl faces the first memory die 101, the interconnect die 102 and the second memory die 103. In some embodiments, the molding material layer 41 contacts the bonding layer 51.

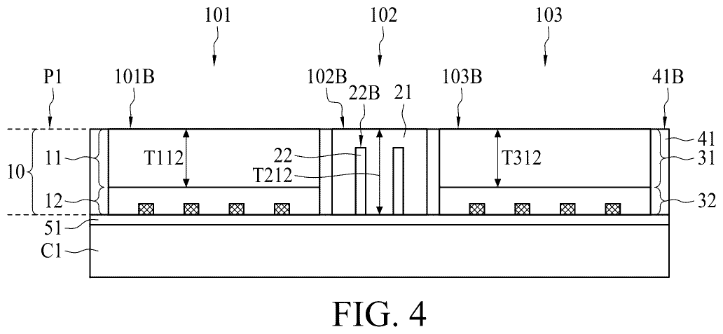

Referring to FIG. 4, a grinding operation is performed. In some embodiments, an upper portion of the molding material layer 41 over the first memory die 101, the interconnect die 102 and the second memory die 103 is removed by the grinding operation. The grinding operation is for purposes of planarization and exposure of the first memory die 101, the interconnect die 102 and the second memory die 103. The thicknesses T111, T211 and T311 of the substrate layers 11, 21 and 31 of the first memory die 101, the interconnect die 102 and the second memory die 103 respectively may or may not be reduced by the grinding operation as long as the back surfaces 101B, 102B and 103B of the substrate layers 11, 21 and 31 respectively are exposed, and a planar surface P1 can be achieved after the grinding operation. However, in order to ensure the exposure of each of the first memory die 101, the interconnect die 102 and the second memory die 103, it 15 is preferable to removal surficial portions of the substrate layers 11, 21 and 31 of the first memory die 101, the interconnect die 102 and the second memory die 103.

In some embodiments, a surficial portion of the substrate layer 11 of the first memory die 101 is removed by the grinding operation. In some embodiments, the thickness of the substrate layer 11 of the first memory die 101 is reduced from the thickness T111 (shown in FIG. 3) to a thickness T112 by the grinding operation. In some embodiments, a surficial portion of the substrate layer 21 of the interconnect die 102 is removed by the grinding operation. In some embodiments, the thickness of the substrate layer 21 of the interconnect die 102 is reduced from the thickness T211 (shown in FIG. 3) to a thickness T212 by the grinding operation. In some embodiments, a surficial portion of the substrate layer 31 of the second memory die 103 is removed by the grinding operation. In some embodiments, the thickness of the substrate layer 31 of the second memory die 103 is reduced from the thickness T311 (shown in FIG. 3) to a thickness T312 by the grinding operation.

The thickness T112 of the substrate layer 11 of the first memory die 101 after the grinding operation is substantially less than the thickness T111 prior to the grinding operation. The thickness T212 of the substrate layer 21 of the interconnect die 102 after the grinding operation is substantially less than the thickness T211 prior to the grinding operation. The thickness T312 of the substrate layer 31 of the second memory die 103 after the grinding operation is substantially less than the thickness T311 prior to the grinding operation.

In some embodiments, the thickness T112 of the substrate layer 11 is in a range of 200 to 500 μm. In some embodiments, the thickness T212 of the substrate layer 21 is in a range of 220 to 520 μm. In some embodiments, the thickness T312 of the substrate layer 31 is substantially equal to the thickness T112 of the substrate layer 11. In some embodiments, the thickness T312 of the substrate layer 31 is in a range of 200 to 500 μm.

For a purpose of illustration and case of understanding, reference numerals 101B, 102B and 103B are used throughout the specification to represent the back surfaces of the substrate layers 11, 21 and 31 respectively at different stages of the manufacturing process. However, the back surfaces 101B, 102B and 103B of the substrate layers 11, 21 and 31 at different stages of the manufacturing process may be at different elevations.

As shown in FIG. 4, the back surface 101B of the substrate layer 11 of the first memory die 101 is substantially aligned with the back surface 102B of the substrate layer 21 of the interconnect die 102, and the back surface 102B of the substrate layer 21 of the interconnect die 102 is substantially aligned with the back surface 103B of the substrate layer 31 of the second memory die 103. In other words, the back surface 101B of the substrate layer 11 of the first memory die 101, the back surface 102B of the substrate layer 21 of the interconnect die 102, and the back surface 103B of the substrate layer 31 of the second memory die 103 are substantially at a same elevation. In some embodiments, the back surface 101B of the substrate layer 11 of the first memory die 101, the back surface 102B of the substrate layer 21 of the interconnect die 102, and the back surface 103B of the substrate layer 31 of the second memory die 103 are substantially coplanar.

The molding material layer 41 includes a top surface 41B at the elevation same as that of the back surface 101B of the substrate layer 11 of the first memory die 101, the back surface 102B of the substrate layer 21 of the interconnect die 102, or the back surface 103B of the substrate layer 31 of the second memory die 103. In some embodiments, the top surface 41B of the molding material layer 41 is substantially coplanar with the back surface 101B of the substrate layer 11, the back surface 102B of the substrate layer 21, and the back surface 103B of the substrate layer 31. The planar surface Pl is thereby provided after the grinding operation. In some embodiments, the planar surface PI is defined by the top surface 41B of the molding material layer 41, the back surface 101B of the substrate layer 11, the back surface 102B of the substrate layer 21, and the back surface 103B of the substrate layer 31. For a purpose of illustration, after the grinding operation, the first memory die 101, the interconnect die 102, the second memory die 103, and the molding material layer 41 are collectively referred to as an intermediate chip 10.

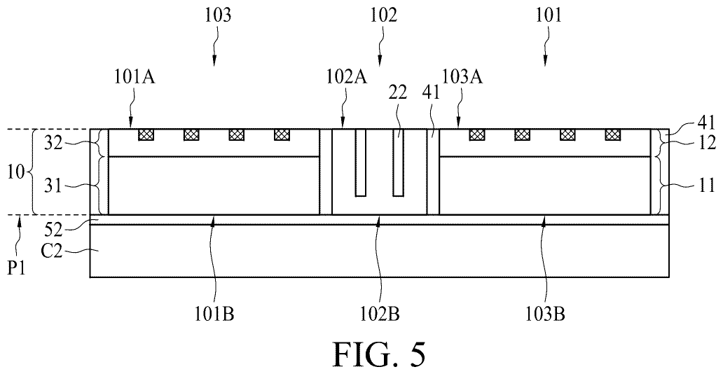

Referring to FIG. 5, the carrier substrate C1 shown in FIG. 4 is detached (or de-bonded), and the intermediate chip 10 is flipped over and attached to a carrier substrate C2. A front surface 101A of the first memory die 101, a front surface 102A of the interconnect die 102, and a front surface 103A of the second memory die 103 are exposed after the detaching of the carrier substrate C1.

In some embodiments, a bonding layer 52 is disposed over the carrier substrate C2. The planar surface P1 is attached to the carrier substrate C2 through the bonding layer 52. In some embodiments, the back surface 101B of the substrate layer 11 of the first memory die 101 is attached to the carrier substrate C2 through the bonding layer 52. In some embodiments, the back surface 102B of the interconnect die 102 is attached to the carrier substrate C2 through the bonding layer 52. In some embodiments, the back surface 103B of the second memory die 103 is attached to the carrier substrate C2 through the bonding layer 52. It should be noted that the back surface 101B of the substrate layer 11 defines a back surface of the first memory die 101, and thus the back surface 101B can also represent the back surface of the first memory die 101. Similarly, the back surface 102B of the substrate layer 21 defines a back surface of the interconnect die 102, and thus the back surface 102B can also represent the back surface of the interconnect die 102; and the back surface 103B of the substrate layer 31 defines a back surface of the second memory die 103, and thus the back surface 103B can also represent the back surface of the second memory die 103.

In some embodiments, the intermediate chip 10 is flipped over prior to the detaching of the carrier substrate C1. In some embodiments, the carrier substrate C2 is attached to the back surfaces 101B, 102B and 103B and the molding material layer 41 of the intermediate chip 10 prior to the detaching of the carrier substrate C1. In some embodiments, the carrier substrate Cl is detached while the intermediate chip 10 is attached to the carrier substrate C2.

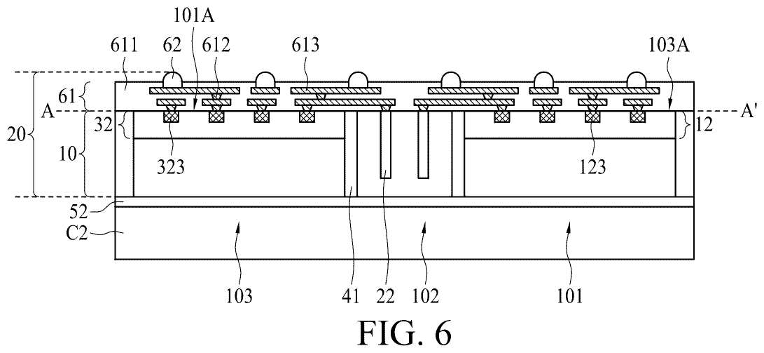

Referring to FIG. 6, a front-side RDL 61 is formed over the intermediate chip 10. In some embodiments, the front-side RDL 61 covers the front surface 101A of the first memory die 101, the front surface 102A of the interconnect die 102 and the front surface 103A of the second memory die 103. In some embodiments, the front-side RDL 61 further covers the molding material layer 41.

The front-side RDL 61 may include multiple conductive elements arranged into layers. The conductive elements may include metal lines 613 and metal vias 612. In some embodiments, the metal lines 613 are arranged into multiple metal line layers. In some embodiments, the metal vias 612 are arranged into multiple metal via layers. The metal via layers are arranged alternately between the metal line layers for electrical connection between the metal line layers. In some embodiments, each metal line layer is formed of metal lines 613 and an IMD layer surrounding the metal lines. In some embodiments, each metal via layer is formed of metal vias and an IMD layer surrounding the metal vias. The front-side RDL 61 includes multiple IMD layers, and the multiple IMD layers are collectively referred to as an IMD structure 611.

As shown in FIG. 6, a plurality of conductive bumps 62 are formed over the front-side RDL 61. Each of the conductive bumps 62 penetrates a top-most IMD layer of the front-side RDL 61 and electrically connects to a metal line 613 disposed in a top-most metal line layer. The conductive bumps 62 are for electrical connection of each of the first memory die 101, the interconnect die 102, and the second memory die 103 to another die, chip, substrate or wafer.

In some embodiments, the via structures 22 electrically connect to one or more of the metal lines 613 through the metal vias 612. In some embodiments, the conductive elements 323 of the interconnect structure 32 electrically connect to one or more of the metal lines 613 through the metal vias 612. In some embodiments, the conductive elements 123 of the interconnect structure 12 electrically connect to one or more of the metal lines 613 through the metal vias 612. For a purpose of illustration, the intermediate chip 10, the front-side RDL 61 and the conductive bumps 62 are collectively referred to as an intermediate chip 20.

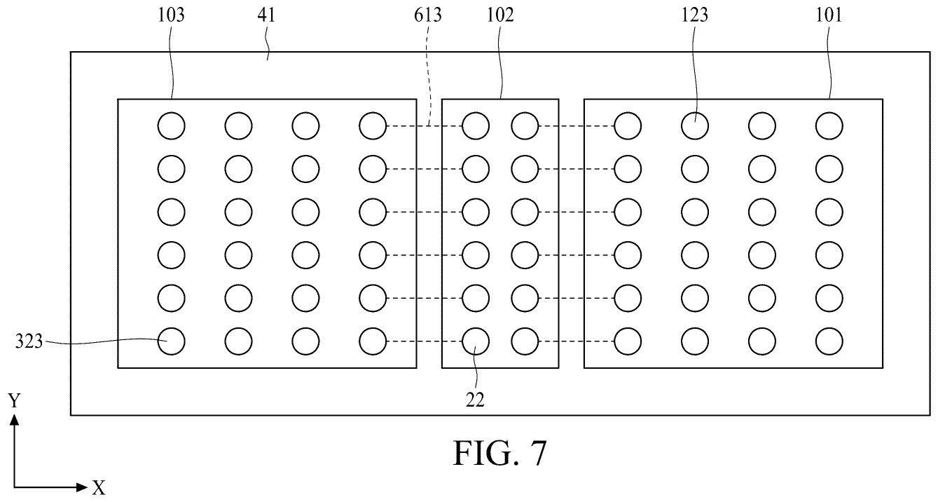

FIG. 7 is a schematic top view of the intermediate chip 10 along a line A-A′ shown in FIG. 6. In some embodiments, the via structures 22 are arranged into two lines, and each line extends along a first horizontal direction (e.g., Y direction). In some embodiments, a first line of the via structures 22 is proximal to the first memory die 101, and a second line of the via structures 22 is proximal to the second memory die 103. In some embodiments, the via structures 22 in the first line are electrically isolated from the via structures 22 in the second line. In some embodiments, the conductive elements at the front surface 101A of the first memory die 101 are arranged into multiple lines along a second horizontal direction (e.g., X direction), and each line extends along the first horizontal direction (e.g., the Y direction).

In some embodiments, the first line of the via structures 22 electrically connects to a line of the conductive elements 123, wherein the line of the conductive elements 123 is a closest line to the interconnect die 102 of the multiple lines. In some embodiments, each of the via structures 22 in the first line of the multiple lines of the via structures 22 is aligned with the conductive elements 123 in the closest line of the multiple lines of the conductive elements 123 along the second direction (e.g., the X direction). In some embodiments, each of the via structures 22 in the first line of the multiple lines of the via structures 22 connects to each of the conductive elements 123 in the closest line of the multiple lines of the conductive elements 123 through a metal line 613 (indicated by a dotted line).

In some embodiments, the second line of the via structures 22 electrically connects to a line of the conductive elements 323, wherein the line of the conductive elements 323 is a closest line to the interconnect die 102 of the multiple lines. In some embodiments, each of the via structures 22 in the second line of the multiple lines of the via structures 22 is aligned with the conductive elements 323 in the closest line of the multiple lines of the conductive elements 323 along the second direction (e.g., the X direction). In some embodiments, each of the via structures 22 in the second line of the multiple lines of the via structures 22 connects to each of the conductive elements 323 in the closest line of the multiple lines of the conductive elements 323 through a metal line 613 (indicated by a dotted line).

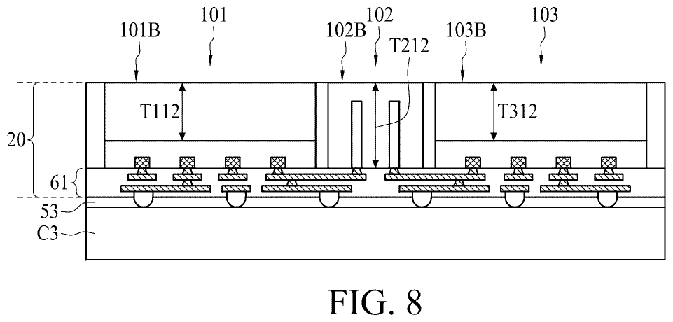

Referring to FIG. 8, the carrier substrate C2 shown in FIG. 6 is detached (or de-bonded), and the intermediate chip 20 is flipped over and attached to a carrier substrate C3. The back surface 101B of the first memory die 101, the back surface 102B of the interconnect die 102, and the back surface 103B of the second memory die 103 are exposed after the detaching of the carrier substrate C2.

In some embodiments, a bonding layer 53 is disposed over the carrier substrate C3. The intermediate chip 20 is attached to the carrier substrate C3 through the bonding layer 52. In some embodiments, the front-side RDL 61 is attached to the carrier substrate C3 through the bonding layer 53. In some embodiments, the top-most IMD layer of the IMD structure 611 contacts the bonding layer 53. In some embodiments, the conductive bumps 62 are embedded in the bonding layer 53. The conductive bumps 62 may or may not penetrate the bonding layer 53.

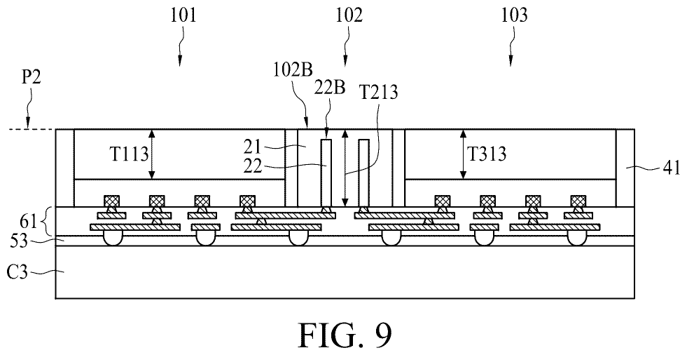

Referring to FIG. 9, a planarization operation is performed. The planarization operation may include a grinding operation, a chemical mechanical polishing (CMP) operation, a wet etching operation, a dry etching operation, or a combination thereof. Thicknesses T112, T212 and T312 of the substrate layers 11, 21 and 31 of the first memory die 101, the interconnect die 102 and the second memory die 103 respectively are reduced by the planarization.

In some embodiments, a surficial portion of the substrate layer 11 of the first memory die 101 is removed by the planarization operation. In some embodiments, the thickness of the substrate layer 11 of the first memory die 101 is reduced from the thickness T112 (shown in FIG. 8) to a thickness T113 by the planarization operation. In some embodiments, a surficial portion of the substrate layer 21 of the interconnect die 102 is removed by the planarization operation. In some embodiments, the thickness of the substrate layer 21 of the interconnect die 102 is reduced from the thickness T212 (shown in FIG. 8) to a thickness T213 by the planarization operation. In some embodiments, a surficial portion of the substrate layer 31 of the second memory die 103 is removed by the planarization operation. In some embodiments, the thickness of the substrate layer 31 of the second memory die 103 is reduced from the thickness T312 (shown in FIG. 8) to a thickness T313 by the planarization operation. In some embodiments, a surficial portion of the molding material layer 41 is removed by the planarization operation, and a planar surface P2 is thereby provided.

The thickness T113 of the substrate layer 11 of the first memory die 101 after the planarization operation is substantially less than the thickness T112. The thickness T213 of the substrate layer 21 of the interconnect die 102 after the planarization operation is substantially less than the thickness T212. The thickness T313 of the substrate layer 11 of the second memory die 103 after the planarization operation is substantially less than the thickness T312.

In some embodiments, the thickness T113 of the substrate layer 11 is in a range of 150 to 300 μm. In some embodiments, the thickness T213 of the substrate layer 21 is in a range of 170 to 400 μm. In some embodiments, the thickness T313 of the substrate layer 31 is substantially equal to the thickness T113 of the substrate layer 11. In some embodiments, the thickness T313 of the substrate layer 31 is in a range of 150 to 300 μm.

Bottoms 22B of the via structures 22 are within the substrate layer 21 after the planarization operation. In some embodiments, the thickness T213 of the substrate layer 21 is substantially less than the depth T221 of the via structure 22 shown in FIG. 2. In some embodiments, each of the bottoms 22B of the via structures 22 is separated from the back surface 102B of the interconnect die 102 (or the back surface of the substrate layer 21).

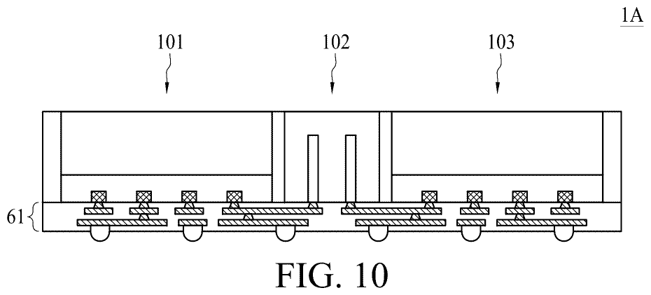

Referring to FIG. 10, the carrier substrate C3 shown in FIG. 9 is detached (or de-bonded) and removed. A reconstructed chip 1A, which can be a top reconstructed chip over a logic wafer as shown in FIG. 1, is thereby formed.

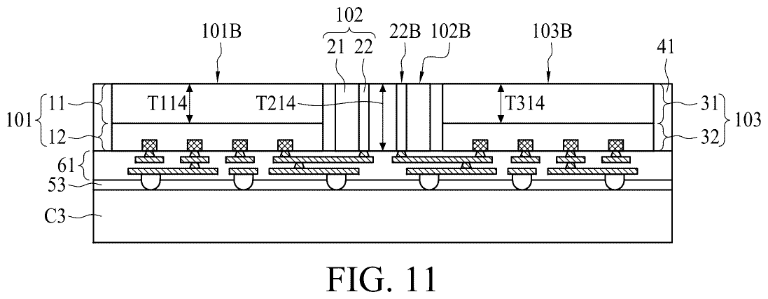

Referring to FIG. 11, another planarization operation may be performed after the operation depicted in FIG. 8 instead of the planarization operation depicted in FIG. 9. The planarization operation shown in FIG. 11 is similar to the planarization operation shown in FIG. 9 except that the planarization operation shown in FIG. 11 stops when the via structures 22 are exposed at the back surface 102B of the interconnect die 102 as shown in FIG. 11.

In some embodiments, the substrate layer 11 has a thickness T114, which is substantially less than the thickness T113 shown in FIG. 9 or the thickness T112 shown in FIG. 8, after the planarization operation as depicted in FIG. 11. In some embodiments, the substrate layer 21 has a thickness T214, which is substantially less than the thickness T213 shown in FIG. 9 or the thickness T212 shown in FIG. 8, after the planarization operation as depicted in FIG. 11. In some embodiments, the substrate layer 31 has a thickness T314, which is substantially less than the thickness T313 shown in FIG. 9 or the thickness T312 shown in FIG. 8, after the planarization operation as depicted in FIG. 11.

In some embodiments, the thickness T214 is substantially equal to the depth T221 of the via structure 22 shown in FIG. 2. In some embodiments, the thickness T214 is in a range of 30 to 70 μm. In some embodiments, the thickness T114 is substantially less than the thickness T214. In some embodiments, the thickness T114 is in a range of 10 to 50 μm. In some embodiments, the thickness T314 is substantially equal to the thickness T114. In some embodiments, the thickness T314 is in a range of 10 to 50 μm.

In alternative embodiments, the planarization operation shown in FIG. 11 further removes bottom portions of the via structures 22 to ensure that all the via structures 22 are exposed. In some embodiments, the thickness T214 is substantially less than the depth T221 of the via structure 22 shown in FIG. 2. In such embodiments, a depth of the via structure 22 after the planarization shown in FIG. 11 is substantially greater than 20 μm.

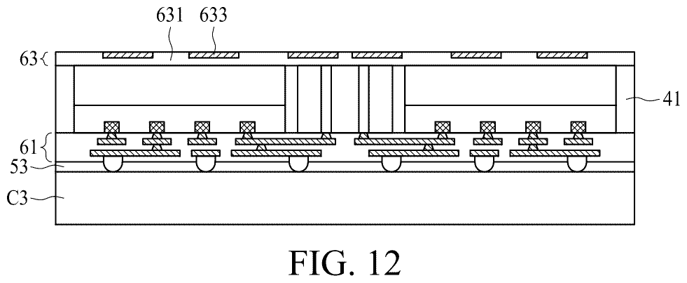

Referring to FIG. 12, a backside RDL 63 is formed over the intermediate structure shown in FIG. 11. In some embodiments, the backside RDL 63 covers the back surface 101B of the first memory die 101, the back surface 102B of the interconnect die 102 and the back surface 103B of the second memory die 103 shown in FIG. 11. In some embodiments, the backside RDL 63 further covers the molding material layer 41.

The backside RDL 63 includes multiple conductive elements arranged into layers. The backside RDL 63 can be similar to the front-side RDL 61 but with a smaller number of layers compared to the front-side RDL 61. Details of a structure of the backside RDL 63 can be found by referring to the front-side RDL 61 described above. For a purpose of illustration and simplicity of figures, only a top-most metal line layer (including multiple metal lines 633) surrounded by an IMD structure 631 (including multiple IMD layers) is depicted in the figures. However, such depiction is not intended to limit the present disclosure. The backside RDL 63 may further include another metal line layer and one or more metal via layers, wherein each metal via layer includes multiple metal vias. In some embodiments, the metal lines 613 in the top-most metal line layer are exposed through the IMD structure 611 for a purpose of electrical connection to another reconstructed chip disposed thereabove during subsequent processing.

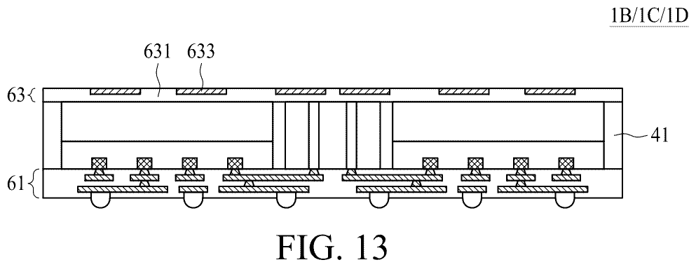

Referring to FIG. 13, the carrier substrate C3 shown in FIG. 12 is detached (or de-bonded) and removed. A reconstructed chip 1B, 1C or 1D, disposed between the logic wafer 6A and the top reconstructed chip 1A as shown in FIG. 1, is thereby formed.

The reconstructed chips 1A, 1B, 1C and 1D can be formed or manufactured following the method as described above and depicted in FIGS. 2 to 13. The reconstructed chips 1A, 1B, 1C and 1D are then be bonded to a logic wafer 6A.

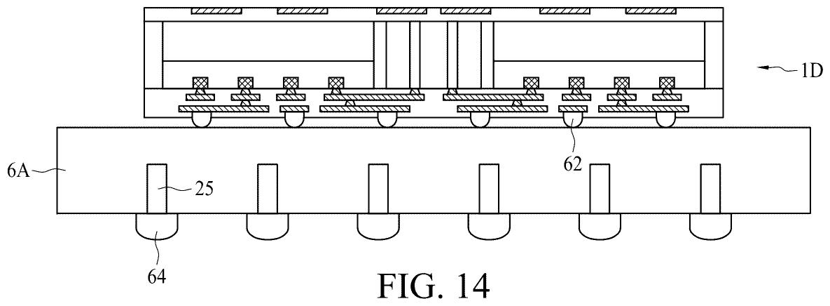

Referring to FIG. 14, the reconstructed chip 1D is disposed, attached or bonded to the logic wafer 6A. In some embodiments, the conductive bumps 62 are electrically connected to the logic wafer 6A. In some embodiments, the logic wafer 6A may include conductive pads at a side of the logic wafer 6A facing the reconstructed chip 1D, and the conductive bumps 62 may contact the conductive pads of the logic wafer 6A, thereby electrically connecting the reconstructed chip 1D to the logic wafer 6A.

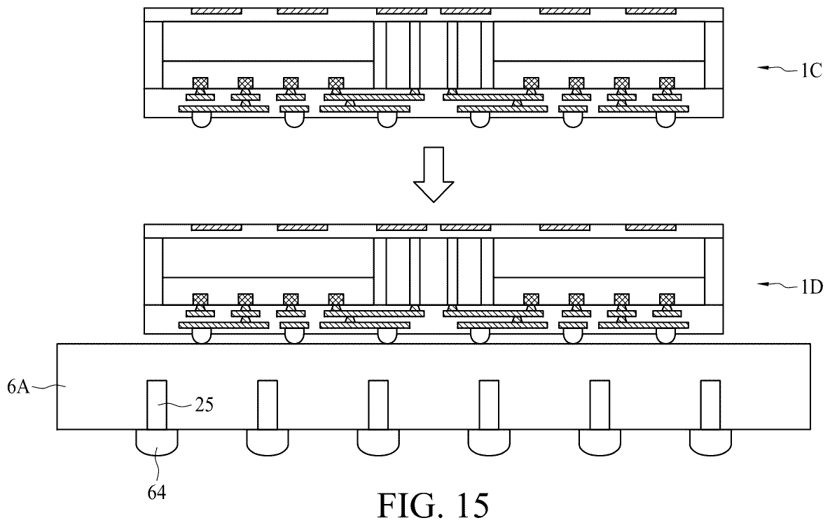

Referring to FIG. 15, the reconstructed chip 1C is disposed over the reconstructed chip 1D. In some embodiments, the reconstructed chip 1C is vertically aligned with the reconstructed chip 1D.

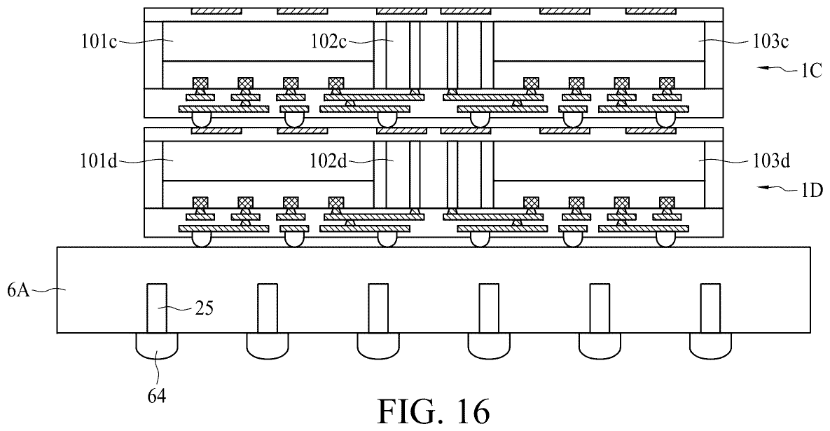

Referring to FIG. 16, the reconstructed chip 1C is bonded to the reconstructed chip 1D. In some embodiments, the reconstructed chip 1C is bonded to the reconstructed chip 1D after the reconstructed chip 1C is aligned with the reconstructed chip 1D as shown in FIG. 15. As a result, the first memory die 101c of the reconstructed chip 1C is vertically aligned with the first memory die 101d of the reconstructed chip 1D; the interconnect die 102c of the reconstructed chip 1C is vertically aligned with the interconnect die 102d of the reconstructed chip 1D; and the second memory die 103c of the reconstructed chip 1C is vertically aligned with the second memory die 102d of the reconstructed chip 1D.

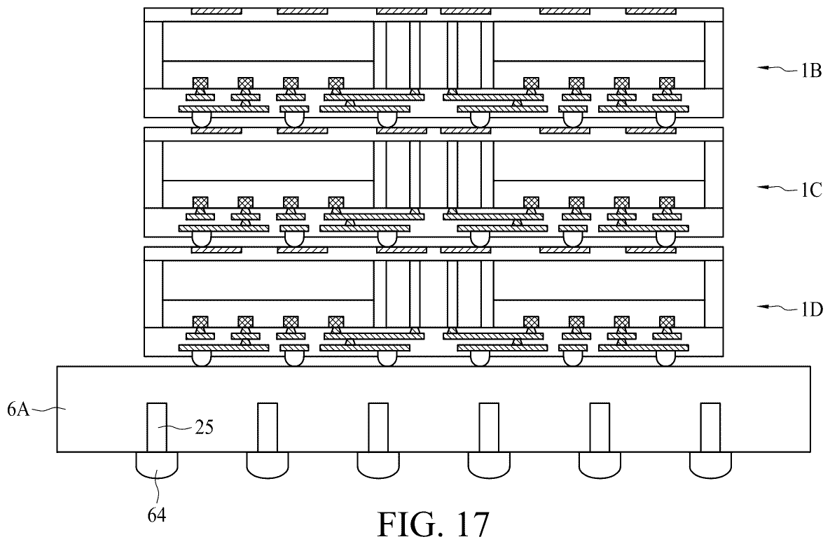

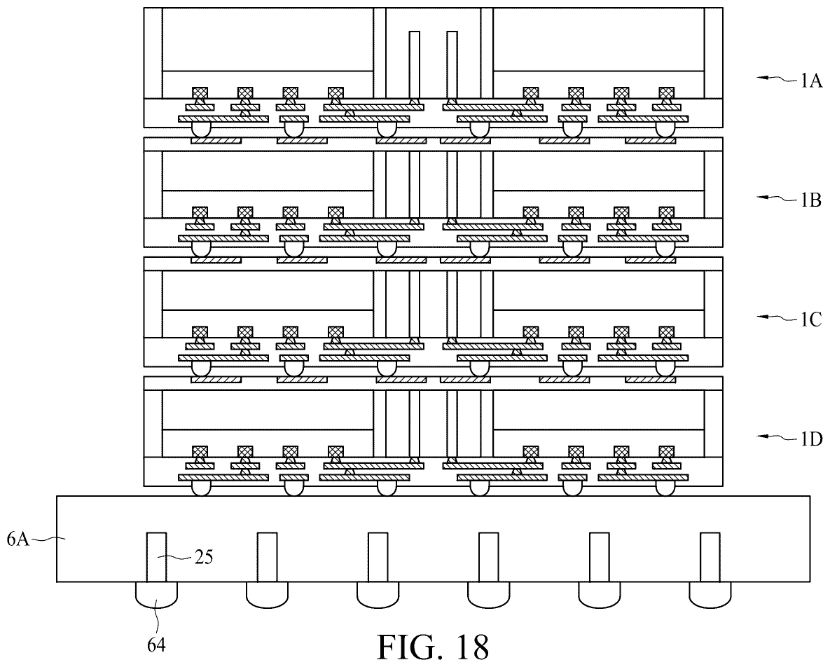

Referring to FIGS. 17 to 18, operations as depicted in FIGS. 15 and 16 are repeated to bond the reconstructed chip 1B to the reconstructed chip 1C, and then bond the reconstructed chip 1A to the reconstructed chip 1B.

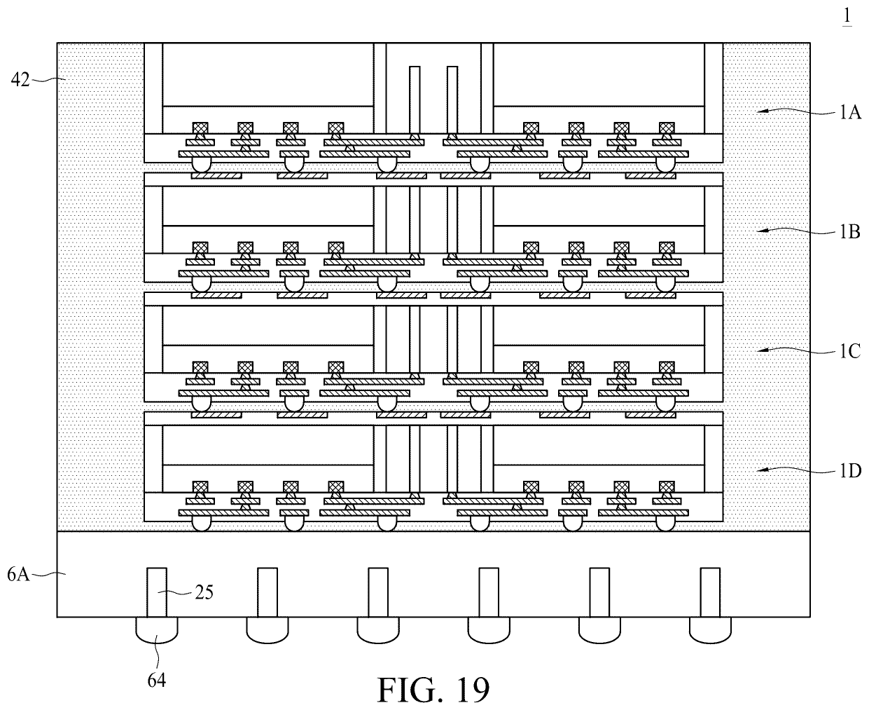

Referring to FIG. 19, a molding material layer 42 is formed surrounding the reconstructed chips 1A, 1B, 1C and 1D. In some embodiments, the molding material layer 42 fills a space between the reconstructed chips 1A and 1B. In some embodiments, the molding material layer 42 fills a space between the reconstructed chips 1B and 1C. In some embodiments, the molding material layer 42 fills a space between the reconstructed chips 1C and 1D. In some embodiments, the molding material layer 42 fills a space between the reconstructed chip 1D and the logic wafer 6A. In some embodiments, a top surface of the molding material layer 42 is substantially aligned with a top surface of the reconstructed chip 1A. In some embodiments, the top surface of the molding material layer 42 and the top surface of the reconstructed chip 1A are substantially coplanar.

Referring back to FIGS. 1 and 19, signals (or data stored in the first memory die 101d) can be transmitted from the first memory die 101d to the logic wafer 6A through the front-side RDL 61d. In some embodiments, signals (or data stored in the first memory die 101c) can be transmitted from the first memory die 101c to the logic wafer 6A through the front-side RDL 61c, the backside RDL 63d, the via structure 102d, and the front-side RDL 61d. In some embodiments, signals (or data stored in the first memory die 101b) can be transmitted from the first memory die 101b to the logic wafer 6A through the front-side RDL 61b, the backside RDL 63c, the via structure 102c, the front-side RDL 61c, the backside RDL 63d, the via structure 102d, and the front-side RDL 61d. In some embodiments, signals (or data stored in the first memory die 101a) can be transmitted from the first memory die 101a to the logic wafer 6A through the front-side RDL 61a, the backside RDL 63b, the via structure 102b, the front-side RDL 61b, the backside RDL 63c, the via structure 102c, the front-side RDL 61c, the backside RDL 63d, the via structure 102d, and the front-side RDL 61d.

Similarly, in some embodiments, signals (or data stored in the second memory die 103d) can be transmitted from the second memory die 103d to the logic wafer 6A through the front-side RDL 61d. In some embodiments, signals (or data stored in the second memory die 101c) can be transmitted from the second memory die 103c to the logic wafer 6A through the front-side RDL 61c, the backside RDL 63d, the via structure 102d, and the front-side RDL 61d. In some embodiments, signals (or data stored in the second memory die 103b) can be transmitted from the second memory die 103b to the logic wafer 6A through the front-side RDL 61b, the backside RDL 63c, the via structure 102c, the front-side RDL 61c, the backside RDL 63d, the via structure 102d, and the front-side RDL 61d. In some embodiments, signals (or data stored in the second memory die 103a) can be transmitted from the second memory die 103a to the logic wafer 6A through the front-side RDL 61a, the backside RDL 63b, the via structure 102b, the front-side RDL 61b, the backside RDL 63c, the via structure 102c, the front-side RDL 61c, the backside RDL 63d, the via structure 102d, and the front-side RDL 61d.

A traditional DRAM stacked structure includes only vertically arranged DRAM dies, and electrical transmission is achieved through vias disposed within the DRAM dies. However, the DRAM dies are not able to be horizontally connected, and thus there is no horizontal arrangement of the DRAM dies. A size of the stacked structure cannot be further reduced without reducing a total number of the DRAM dies. In addition, the through vias disposed in a DRAM die occupy a certain amount of area, and thus a size of the DRAM cannot be further reduced, and circuit design of the DRAM die is complicated.

Compared to the traditional DRAM stacked structure, the semiconductor structure of the present disclosure includes horizontally arranged DRAM dies in a reconstructed chip, and multiple reconstructed chips can be vertically stacked. Therefore, the semiconductor structure of the present disclosure, compared to the traditional DRAM stacked structure, can provide reduced size under a condition of same numbers of DRAM dies, or better performance and a greater number of DRAM dies under a condition of same sizes of the final structures.

It should be noted that the via structures 22a in the top-most reconstructed chip 1A can be considered as dummy via structures. In other words, the via structures 22a in the top-most reconstructed chip 1A do not function during the operation. In alternative embodiments, the via structures 22a in the interconnect die 102a of the top-most reconstructed chip 1A can be absent.

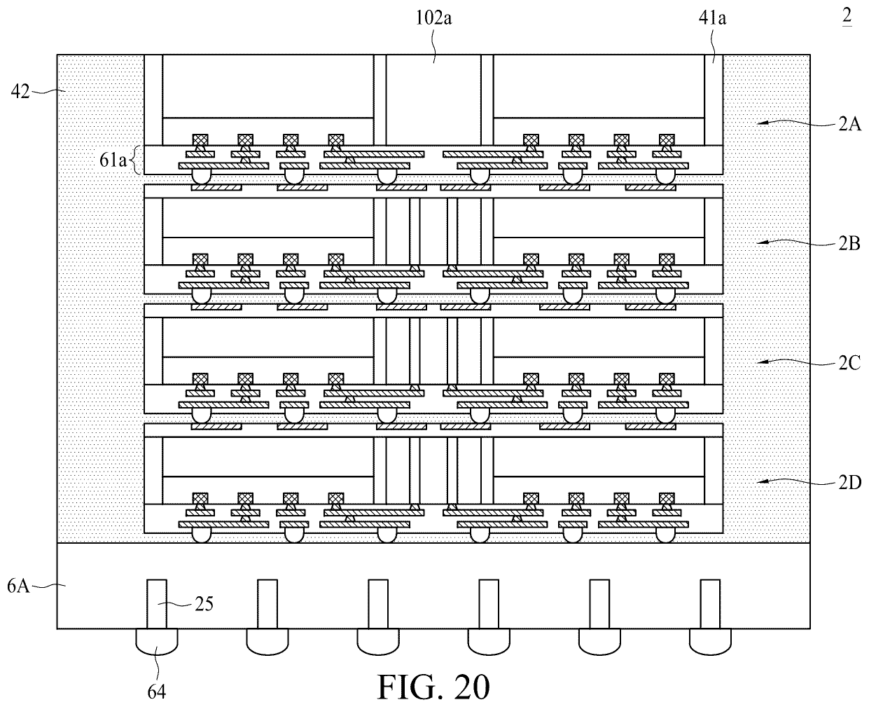

Referring to FIG. 20, a semiconductor structure 2 in accordance with some embodiments of the present disclosure is provided. The semiconductor structure 2 is similar to the semiconductor structure 1 shown in FIGS. 1 and 19, except that via structures 22a are absent in an interconnect die 102a of a top-most reconstructed chip 1A.

It should be noted that in the present disclosure, multiple embodiments of the present invention having an inventive concept same as that described above are provided. For a purpose of clarity and simplicity, reference numerals of elements with same or similar functions are repeated in different embodiments. However, such usage is not intended to limit the present disclosure to specific embodiments or specific elements. For a purpose of brevity, only differences from other embodiments are emphasized in the following specification, and descriptions of similar or same elements, functions and properties are omitted. In addition, conditions or parameters described in different embodiments can be combined or modified to form different combinations of embodiments as long as the parameters or conditions used are not in conflict.

As shown in FIG. 20, the interconnect die 102a of the top-most reconstructed chip 1A does not include any via structure. In addition, there is no metal via connected to the interconnect die 102a. In the embodiments of FIG. 20, the interconnect die 102a does not provide a function of electrical transmission. The presence of the interconnect die 102a is merely for a purpose of requiring fewer changes to the manufacturing process. In some embodiments, the interconnect die 102a can provide better support to the reconstructed chip 1A. In other embodiments, the interconnect die 102a is absent in the top-most reconstructed chip 1A, and the molding material layer 41a fills a space between the first memory die 101a and the second memory die 103a (not shown in the figures).

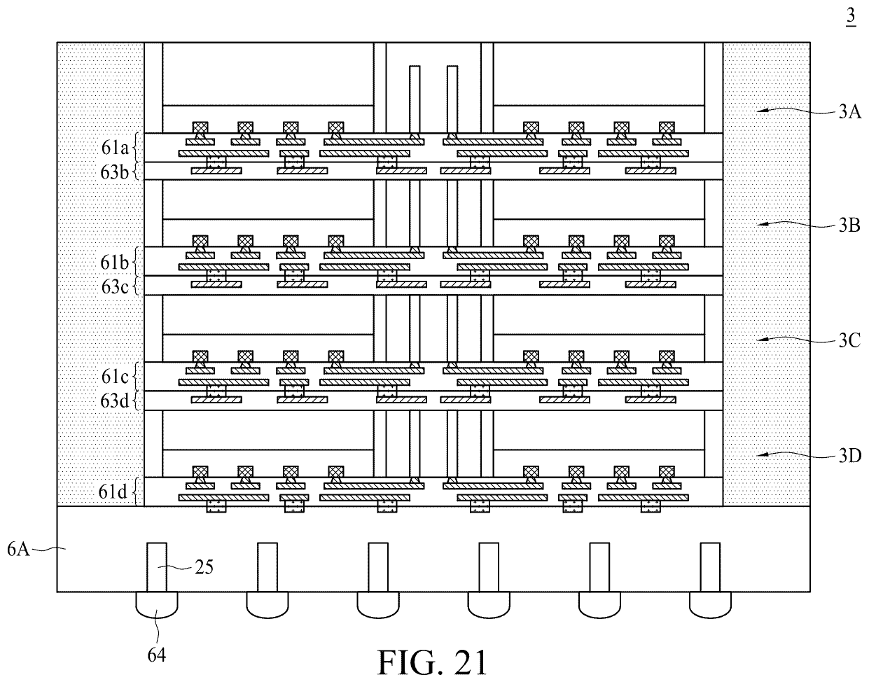

Referring to FIG. 21, a semiconductor structure 3 in accordance with some embodiments of the present disclosure is provided. The semiconductor structure 3 is similar to the semiconductor structure 1 shown in FIGS. 1 and 19, except that reconstructed chips 2A, 2B, 2C and 2D do not include the conductive bumps 62.

The reconstructed chips 1A, 1B, 1C and 1D of the semiconductor structure 1 are bonded using the conductive bumps 62 (as shown in FIGS. 10 and 13). However, the present disclosure is not limited thereto. The semiconductor structure 2 may include the reconstructed chips 2A, 2B, 2C and 2D, and the reconstructed chips 2A, 2B, 2C and 2D are bonded by hybrid bonding instead of by the conductive bumps 62.

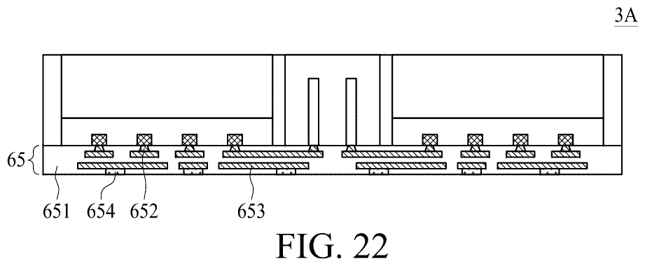

Referring to FIG. 22, FIG. 22 shows a schematic cross-sectional diagram of the top-most reconstructed chip 3A. The reconstructed chip 3A includes a front-side RDL 65 instead of the front-side RDL 61 shown in FIG. 10. In some embodiments, the front-side RDL 65 includes an IMD structure 651, metal vias 652, metal lines 653, and conductive segments 654. The front-side RDL 65 is similar to the front-side RDL 61, but further includes the conductive segments 654 exposed through a top-most IMD layer of the IMD structure 651. The conductive segments 654 are for electrical connection and hybrid bonding to another reconstructed chip.

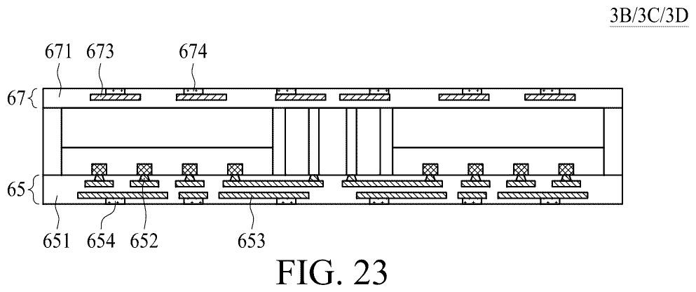

Referring to FIG. 23, FIG. 23 shows a schematic cross-sectional diagram of a reconstructed chip 3B, 3C or 3D. The reconstructed chip 3B, 3C or 3D includes a front-side RDL 65 similar to the front-side RDL 65 of the reconstructed chip 3A as illustrated in FIG. 22, and a backside RDL 67. In some embodiments, the backside RDL 67 includes an IMD structure 671, metal vias (not shown), metal lines 673, and conductive segments 674. The backside RDL 67 is similar to the backside RDL 63 shown in FIG. 13, but further includes the conductive segments 674 exposed through a top-most IMD layer of the IMD structure 671. The conductive segments 674 are for electrical connection and hybrid bonding to another reconstructed chip.

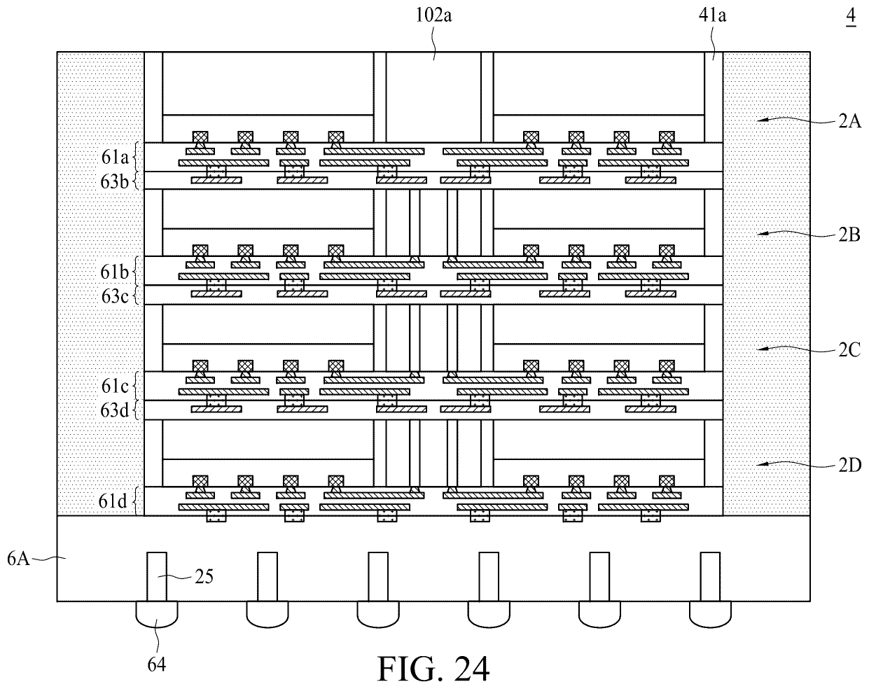

Referring to FIG. 24, a semiconductor structure 4 in accordance with some embodiments of the present disclosure is provided. The semiconductor structure 4 is similar to the semiconductor structure 3 shown in FIG. 21 except that via structures 22a are absent in an interconnect die 102a of a top-most reconstructed chip 1A.

As shown in FIG. 24, the interconnect die 102a of the top-most reconstructed chip 4A does not include any via structure. In addition, there is no metal via connected to the interconnect die 102a. In the embodiments of FIG. 24, the interconnect die 102a does not provide function of electrical transmission. The presence of the interconnect die 102a is for a purpose of requiring fewer changes to the manufacturing process. In some embodiments, the interconnect die 102a can provide better support to the reconstructed chip 4A. In other embodiments, the interconnect die 102a is absent in the top-most reconstructed chip 4A, and the molding material layer 41a fills a space between the first memory die 101a and the second memory die 103a (not shown in the figures).

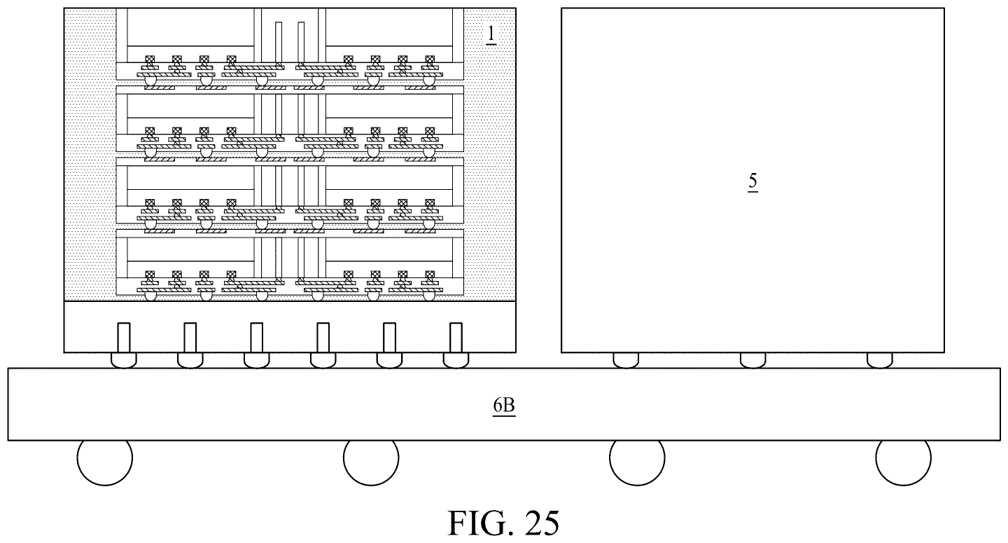

Referring to FIG. 25, the semiconductor structure 1, 2, 3 or 4 as described above can be applied in a semiconductor package. For example, the semiconductor structure 1 can be bonded to a substrate or an interposer 6B. In some embodiments, the semiconductor package shown in FIG. 25 can further include a central processing unit (CPU).

To conclude description of manufacturing processes of the embodiments as described above, a method S1 is provided.

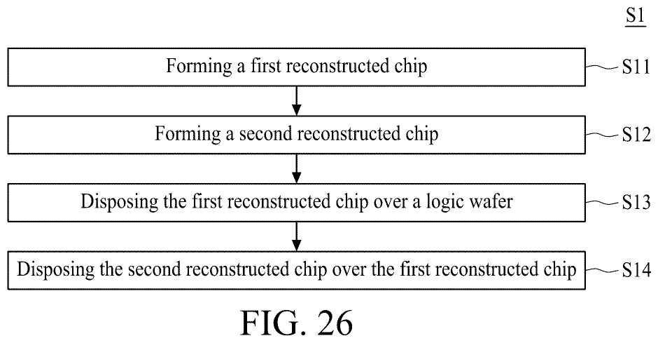

FIG. 26 is a flow diagram of the method S1 for manufacturing a semiconductor structure in accordance with some embodiments of the present disclosure. The method S1 includes a number of operations (S11, S12, S13 and S14), and the description and illustration are not deemed as a limitation to the sequence of the operations. In the operation S11, a first reconstructed chip is formed. In the operation S12, a second reconstructed chip is formed. In the operation S13, the first reconstructed chip is disposed over a logic wafer. In the operation S14, the second reconstructed chip is disposed over the first reconstructed chip.

Each of the operations S11, S12, S13 and S14 can include multiple steps.

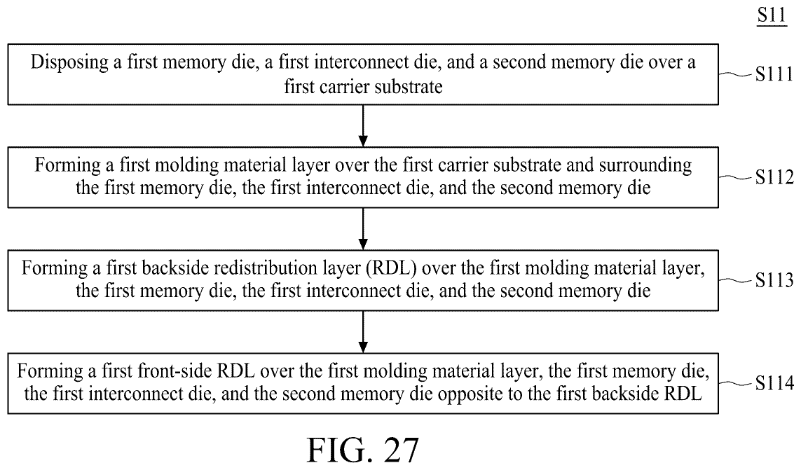

FIG. 27 is a flow diagram of the operation S11 for forming the first reconstructed chip in accordance with some embodiments of the present disclosure. The operation S11 includes a number of steps (S111, S112, S113 and S114), and the description and illustration are not deemed as a limitation to the sequence of the steps. In the step S111, a first memory die, a first interconnect die, and a second memory die are disposed over a first carrier substrate. In the step S112, a first molding material layer is formed over the first carrier substrate, wherein the first molding material layer surrounds the first memory die, the first interconnect die, and the second memory die. In the step S113, a first front-side redistribution layer (RDL) is formed over the first molding material layer, the first memory die, the first interconnect die, and the second memory die. In the step S114, a first backside RDL is formed over the first molding material layer, the first memory die, the first interconnect die, and the second memory die opposite to the first front-side RDL, thereby forming the first reconstructed chip.

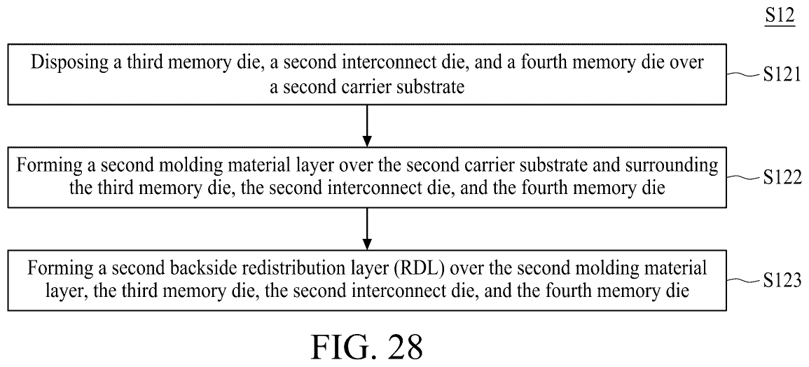

FIG. 28 is a flow diagram of the operation S12 for forming the second reconstructed chip in accordance with some embodiments of the present disclosure. The operation S12 includes a number of steps (S121, S122 and S123), and the description and illustration are not deemed as a limitation to the sequence of the steps. In the step S121, a third memory die, a second interconnect die, and a fourth memory die are disposed over a second carrier substrate. In the step S122, a second molding material layer is formed over the second carrier substrate and surrounds the third memory die, the second interconnect die, and the fourth memory die. In the step S123, a second front-side RDL is formed over the second molding material layer, the third memory die, the second interconnect die, and the fourth memory die, thereby forming the second reconstructed chip.

The operations of the method S1 can be rearranged or otherwise modified within the scope of the various aspects. In some embodiments, additional processes are provided before, during, and after the method S1, and some other processes are only briefly described herein.

Therefore, the present disclosure provides a novel configuration of stacked memory dies. The semiconductor structure of the present disclosure includes horizontally arranged DRAM dies in a reconstructed chip, and multiple reconstructed chips can be vertically stacked. Therefore, the semiconductor structure of the present disclosure can provide reduced size compared to the traditional DRAM stacked structure under a condition of same numbers of DRAM dies, or better performance and a greater number of DRAM dies under a condition of same sizes of the final structures.

One aspect of the present disclosure provides a semiconductor structure. The semiconductor structure includes: a logic wafer; a first front-side redistribution layer (RDL), disposed over the logic wafer; a first memory die, disposed over the first front-side RDL; a second memory die, disposed over the first front-side RDL, wherein the first memory die and the second memory die are horizontally arranged; and a first interconnect die, disposed over the first front-side RDL between the first memory die and the second memory die, wherein the first memory die is electrically connected to a first via in the first interconnect die, and the second memory die is electrically connected to a second via in the first interconnect die.

In some embodiments, the first memory die is electrically connected to the first via in the first interconnect die through the first front-side RDL.

In some embodiments, the second memory die is electrically connected to the second via in the first interconnect die through the first front-side RDL.

In some embodiments, the first memory die and the second memory die individually are electrically connected to the logic wafer through the first front-side RDL.

In some embodiments, the first via and the second via penetrate through the first interconnect die.

In some embodiments, a thickness of the first interconnect die is in a range of 30 to 70 microns.

In some embodiments, the first front-side RDL, the first memory die, the second memory die and the first interconnect die are disposed in a first reconstructed chip, and the semiconductor structure further comprises: a second reconstructed chip, disposed over the first reconstructed chip, wherein the second reconstructed chip includes: a second front-side RDL, disposed over and electrically connected to the first reconstructed chip; a third memory die, disposed over the second front-side RDL; a fourth memory die, disposed over the second front-side RDL, wherein the third memory die and the fourth memory die are horizontally arranged; and a second interconnect die, disposed over the second front-side RDL between the third memory die and the fourth memory die, wherein the third memory die is electrically connected to a third via in the second interconnect die, and the fourth memory die is electrically connected to a fourth via in the second interconnect die.

In some embodiments, the first reconstructed chip further includes: a first backside RDL, disposed over the first memory die, the first interconnect die, and the second memory die, wherein the second front-side RDL is electrically connected to the first backside RDL.

In some embodiments, the second front-side RDL is electrically connected to the first backside RDL through conductive bumps.

In some embodiments, the second front-side RDL is electrically connected to the first backside RDL through conductive elements and dielectric layers of the second front-side RDL and the first backside RDL.

In some embodiments, the first via and the second via penetrate through the first interconnect die, and the third via and the fourth via stop within the second interconnect die.

In some embodiments, a thickness of the first interconnect die is substantially less than a thickness of the second interconnect die.

In some embodiments, the third memory die is electrically connected to the logic wafer through the first via or the second via in the first interconnect die.

In some embodiments, the third memory die and the first memory die are vertically aligned.

In some embodiments, the fourth memory die and the second memory die are vertically aligned.

In some embodiments, the first interconnect die and the second interconnect die are vertically aligned.

Another aspect of the present disclosure provides a semiconductor structure. The semiconductor structure includes: a first reconstructed chip, disposed over a logic wafer; and a second reconstructed chip, disposed vertically over the first reconstructed chip. The first reconstructed chip includes: a first front-side redistribution layer (RDL); a first memory die, disposed over the first front-side RDL; a second memory die, disposed over the first front-side RDL, wherein the second memory die and the first memory die are horizontally arranged; and a first interconnect die, disposed over the first front-side RDL and between the first memory die and the second memory die. The second reconstructed chip includes: a second front-side RDL; a third memory die, disposed over the second front-side RDL, wherein a thickness of the third memory die is substantially greater than a thickness of the first memory die; and a fourth memory die, disposed over the front-side RDL and adjacent to the third memory die, wherein a thickness of the fourth memory die is substantially greater than a thickness of the second memory die.

In some embodiments, the first interconnect die includes a first via and a second via adjacent to the first via, and the first via and the second via are electrically isolated from each other.

In some embodiments, the second reconstructed chip further comprises: a second interconnect die, disposed over the second front-side RDL and between the third memory die and the fourth memory die, wherein a via structure is absent in the second interconnect die.

In some embodiments, the second reconstructed chip further comprises: a second interconnect die, disposed over the second front-side RDL and between the third memory die and the fourth memory die, wherein the second interconnect die includes a substrate layer and a plurality of via structures stopping within the substrate layer.

Another aspect of the present disclosure provides a method for manufacturing a semiconductor structure. The method includes a number of operations. A first reconstructed chip is formed. A second reconstructed chip is formed. The first reconstructed chip is disposed over a logic wafer. The second reconstructed chip is disposed over the first reconstructed chip. The formation of the first reconstructed chip includes a number of steps. A first memory die, a first interconnect die, and a second memory die are disposed over a first carrier substrate. A first molding material layer is formed over the first carrier substrate and surrounds the first memory die, the first interconnect die, and the second memory die. A first backside redistribution layer (RDL) is formed over the first molding material layer, the first memory die, the first interconnect die, and the second memory die. A first front-side RDL is formed over the first molding material layer, the first memory die, the first interconnect die, and the second memory die opposite to the first backside RDL, thereby forming the first reconstructed chip. The formation of the second reconstructed chip includes a number of steps. A third memory die, a second interconnect die, and a fourth memory die are disposed over a second carrier substrate. A second molding material layer is formed over the second carrier substrate and surrounds the third memory die, the second interconnect die, and the fourth memory die. A second front-side RDL is formed over the second molding material layer, the third memory die, the second interconnect die, and the fourth memory die, thereby forming the second reconstructed chip.

In some embodiments, the formation of the first reconstructed chip further comprises: performing a grinding operation after the formation of the first molding material layer on backsides of the first memory die, the first interconnect die, and the second memory die, thereby forming a planar surface at the backsides of the first memory die, the first interconnect die, and the second memory die.

In some embodiments, the method further comprises: detaching the first carrier substrate from the first memory die, the first interconnect die, and the second memory die; and prior to the formation of the first front-side RDL, attaching a second carrier substrate on the planar surface at the backsides of the first memory die, the first interconnect die, and the second memory die.

In some embodiments, the method further comprises: after the formation of the first front-side RDL, detaching the second carrier substrate from the first memory die, the first interconnect die, and the second memory die.

In some embodiments, the formation of the first reconstructed chip further comprises: prior to the formation of the first backside RDL, reducing a thickness of the first interconnect die until each of a plurality of vias disposed in the first interconnect die is exposed.

In some embodiments, after the reducing of the thickness of the first interconnect die, the thickness of the first interconnect die is in a range of 30 to 70 microns.

In some embodiments, the formation of the first reconstructed chip further comprises: reducing a thickness of the first memory die concurrently with the reducing of the thickness of the first interconnect die.

In some embodiments, the formation of the first reconstructed chip further comprises: reducing a thickness of the second memory die concurrently with the reducing of the thickness of the first interconnect die.

In some embodiments, the method further comprises: aligning the second reconstructed chip over the first reconstructed chip; and bonding the first backside RDL of the first reconstructed chip to the second front-side RDL of the second reconstructed chip.

In some embodiments, the formation of the second reconstructed chip further comprises: after the formation of the second front-side RDL, reducing thicknesses of the first interconnect die, the third memory die and the fourth memory die.

In some embodiments, bottoms of vias disposed in the second interconnect die remain covered after the reducing of the thicknesses of the second interconnect die, the third memory die and the fourth memory die.

In some embodiments, after the reducing of the thicknesses of the second interconnect die, the third memory die and the fourth memory die, the thickness of the second interconnect die is in a range of 60 to 200 microns.

In some embodiments, the method further comprises: forming a third molding material layer over the logic wafer and surrounding the first reconstructed chip and the second reconstructed chip.

In some embodiments, the method further comprises: attaching the logic wafer to an interposer.

In some embodiments, the first molding material layer is identical to the second molding material layer.

In conclusion, the application discloses a semiconductor structure and a method of manufacturing the same. The present disclosure provides a novel configuration of stacked memory dies. The semiconductor structure of the present disclosure includes horizontally arranged DRAM dies in a reconstructed chip, wherein multiple reconstructed chips can be vertically stacked. Therefore, the semiconductor structure of the present disclosure, in comparison to the traditional DRAM stacked structure, can provide reduced size under a condition of same numbers of DRAM dies, or better performance and a greater number of DRAM dies under a condition of same sizes of the final structures.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A method for manufacturing a semiconductor structure, comprising:
forming a first reconstructed chip, comprising:
disposing a first memory die, a first interconnect die, and a second memory die over a first carrier substrate;
forming a first molding material layer over the first carrier substrate and surrounding the first memory die, the first interconnect die, and the second memory die;
forming a first backside redistribution layer (RDL) over the first molding material layer, the first memory die, the first interconnect die, and the second memory die;
forming a first front-side RDL over the first molding material layer, the first memory die, the first interconnect die, and the second memory die opposite to the first backside RDL, thereby forming the first reconstructed chip;
forming a second reconstructed chip, comprising:
disposing a third memory die, a second interconnect die, and a fourth memory die over a second carrier substrate;
forming a second molding material layer over the second carrier substrate and surrounding the third memory die, the second interconnect die, and the fourth memory die;
forming a second backside redistribution layer (RDL) over the second molding material layer, the third memory die, the second interconnect die, and the fourth memory die, thereby forming the second reconstructed chip;
disposing the first reconstructed chip over a logic wafer; and
disposing the second reconstructed chip over the first reconstructed chip.

2. The method of claim 1, wherein the formation of the first reconstructed chip further comprises:
performing a grinding operation after the formation of the first molding on backsides of the first memory die, the first interconnect die, and the second memory die, thereby forming a planar surface at the backsides of the first memory die, the first interconnect die, and the second memory die.

3. The method of claim 2, further comprising:
detaching the first carrier substrate from the first memory die, the first interconnect die, and the second memory die; and
prior to the formation of the first front-side RDL, attaching a second on the planar surface at the backsides of the first memory die, the first interconnect die, and the second memory die.

4. The method of claim 3, further comprising:
after the formation of the first front-side RDL, detaching the second carrier substrate from the first memory die, the first interconnect die, and the second memory die.

5. The method of claim 1, wherein the formation of the first reconstructed chip further comprises:
prior to the formation of the first backside RDL, reducing a thickness of the first interconnect die until each of a plurality of vias disposed in the first interconnect being exposed.

6. The method of claim 5, wherein the thickness of the first interconnect die is in a range of 30 to 70 microns after the reducing the thickness of the first interconnect die.

7. The method of claim 5, wherein the formation of the first reconstructed chip further comprises:
reducing a thickness of the first memory die concurrently with the reducing the thickness of the first interconnect die.

8. The method of claim 5, wherein the formation of the first reconstructed chip further comprises:
reducing a thickness of the second memory die concurrently with the reducing the thickness of the first interconnect die.

9. The method of claim 1, further comprising:
aligning the second reconstructed chip over the first reconstructed chip; and
bonding the first backside RDL of the first reconstructed chip and the second front-side RDL of the second reconstructed chip.

10. The method of claim 1, wherein the formation of the second reconstructed chip further comprises:
after the formation of the second front-side RDL, reducing thicknesses of the first interconnect die, the third memory die and the fourth memory die.

11. The method of claim 10, wherein bottoms of vias disposed in the second interconnect die remain covered after the reducing the thicknesses of the second interconnect die, the third memory die and the fourth memory die.

12. The method of claim 10, wherein after the reducing the thicknesses of the second interconnect die, the third memory die and the fourth memory die, the thickness of the second interconnect die is in a range of 60 to 200 microns.

13. The method of claim 1, further comprising:
forming a third molding material layer over the logic wafer and surrounding the first reconstructed chip and the second reconstructed chip.

14. The method of claim 1, further comprising:
attaching the logic wafer to an interposer.

15. The method of claim 1, wherein the first molding material layer is identical with the second molding material layer.
